(19) United States
(12) Patent Application Publication
(10) Pub. No.: US 2018/0182909 A1
(43) Pub. Date: Jun. 28, 2018

(54) SOLAR CELL MODULE AND METHOD FOR MANUFACTURING SOLAR CELL MODULE

(71) Applicant: MITSUBISHI ELECTRIC CORPORATION, Chiyoda-ku, Tokyo (JP)

(72) Inventors: Yosuke INOUE, Tokyo (JP); Takayoshi MATSUDA, Chiyoda-ku, Tokyo (JP); Yuki HASEGAWA, Tokyo (JP); Tatsuya ISHIGAKI, Tokyo (JP)

(73) Assignee: MITSUBISHI ELECTRIC CORPORATION, Chiyoda-ku, Tokyo (JP)

(21) Appl. No.: 15/735,232

(22) PCT Filed: Jun. 17, 2015
(86) PCT No.: PCT/JP2015/067517

§ 371 Date: Dec. 11, 2017

(51) Int. Cl. H01L 31/049; H01L 31/048; H01L 31/02; H01L 31/18

(52) U.S. Cl. CPC H01L 31/049; H01L 31/18; H01L 31/02008; H01L 31/0481

(57) ABSTRACT

The solar cell module includes a plurality of solar cells that are sealed inside the sealing layer made of resin with light transmission properties, an identification label sheet that is sealed inside the sealing layer in a region different from the solar cells in a planar direction of the light transmissive substrate, and that is made of resin on which identification management information is noted, and a protective sheet that is stacked on the identification label sheet on the side of the light transmissive substrate, sealed inside the sealing layer, made of resin with light transmission properties, and contains therein ultraviolet absorbent. The protective sheet has greater ultraviolet absorbing properties in a specific thickness than a light-receiving-side sealing layer of the sealing layer, which is positioned on the side of the light transmissive substrate relative to a light-receiving surface of the solar cells in a thickness direction of the sealing layer.

### FIELD

The present invention relates to a solar cell module in which solar cells are sealed by a sealant made of resin material, and also relates to a method for manufacturing the solar cell module.

### BACKGROUND

As a conventional sealant for a solar cell module, an ethylene-vinyl acetate copolymer (EVA) has been commonly used. At the time of manufacturing a solar cell module, a light transmissive substrate such as a glass substrate, a light-receiving-side sealing layer made of EVA, a solar cell array, a backside sealing layer made of EVA, and a back film that is a backside cover film are stacked sequentially. It is common that the conventionally-used sealant for a solar cell module is added with an ultraviolet absorbent in order to improve the light resistance of the solar cell module.

Patent Literature 1 discloses a sealant, to which an additive is added aside from an ultraviolet absorbent in order to improve the power generation performance of a solar cell module. Therefore, the disclosed sealant is added with a small amount of ultraviolet absorbent, that is, the sealant has a low ultraviolet absorbing capability.

One of the members to be assembled to a solar cell module is an identification label sheet. The identification label sheet is a sheet specifically designed to be installed within a solar cell module, in which the identification number such as a bar code is marked on resin of polyethylene terephthalate (PET) or the like. The identification label sheet is a necessary member for identifying and managing a manufactured solar cell module. The identification label sheet is sometimes made of a different material from a sealant that seals a solar cell array.

### CITATION LIST

### Patent Literature

Japanese Patent No. 4890752

### SUMMARY

### Technical Problem

However, in accordance with the technique in Patent Literature 1 described above, because of the use of a sealant added with a small amount of ultraviolet absorbent, an identification label sheet is irradiated with a considerable amount of ultraviolet rays. In this case, when a solar cell module is used outdoors, there is a possibility that the identification label sheet may be discolored due to ultraviolet irradiation. In a case where the identification label sheet has been discolored, there is a problem in that the information described on the identification label sheet is difficult to identify or cannot be identified.

The present invention has been achieved to solve the above problems, and an object of the present invention is to provide a solar cell module capable of suppressing discoloration of an identification label sheet that is included in the solar cell module to identify and manage the solar cell module.

### Solution to Problem

There is provided a solar cell module according to an aspect of the present invention that includes: a light-receiving-side protective member that is positioned on a light-receiving side, and has light transmission properties; a backside protective member that is positioned on a backside opposite to a light-receiving surface; a sealing layer that is made of resin with light transmission properties, and interposed between the light-receiving-side protective member and the backside protective member; a plurality of solar cells that are electrically connected and sealed inside the sealing layer; an identification label sheet that is sealed inside the sealing layer in a region different from a region of the solar cells in a planar direction of the light-receiving-side protective member, and that is made of resin on which identification management information is noted; and a protective sheet that is stacked on the identification label sheet on a side of the light-receiving-side protective member, sealed inside the sealing layer, made of resin with light transmission properties, and contains therein ultraviolet absorbent, wherein the protective sheet has greater ultraviolet absorbing properties in a specific thickness than a light-receiving-side sealing layer of the sealing layer, which is positioned on a side of the light-receiving-side protective member relative to light-receiving surfaces of the solar cells in a thickness direction of the sealing layer.

### Advantageous Effects of Invention

The solar cell module according to the present invention has an effect where it is possible to obtain a solar cell module capable of suppressing discoloration of an identification label sheet that is included in the solar cell module to identify and manage the solar cell module.

### BRIEF DESCRIPTION OF DRAWINGS

FIG. 1 is a schematic cross-sectional view illustrating a solar cell module according to a first embodiment of the present invention.

FIG. 2 is a flowchart illustrating a procedure of a method for manufacturing the solar cell module according to the first embodiment of the present invention.

FIG. 3 is a schematic cross-sectional view illustrating the method for manufacturing the solar cell module according to the first embodiment of the present invention.

FIG. 4 is a schematic cross-sectional view illustrating the method for manufacturing the solar cell module according to the first embodiment of the present invention.

FIG. 5 is a schematic cross-sectional view illustrating the method for manufacturing the solar cell module according to the first embodiment of the present invention.

FIG. 6 is a schematic cross-sectional view illustrating a solar-cell-module manufacturing device to be used for manufacturing the solar cell module according to the first embodiment of the present invention.

FIG. 7 is a schematic cross-sectional view illustrating a solar cell module according to a second embodiment of the present invention.

FIG. 8 is a schematic cross-sectional view illustrating a method for manufacturing the solar cell module according to the second embodiment of the present invention.

FIG. 9 is a schematic cross-sectional view illustrating the method for manufacturing the solar cell module according to the second embodiment of the present invention.

FIG. 10 is a schematic cross-sectional view illustrating the method for manufacturing the solar cell module according to the second embodiment of the present invention.

FIG. 11 is a schematic plan view illustrating a solar cell module according to a third embodiment of the present invention.

FIG. 12 is an enlarged diagram illustrating an enlarged region in the vicinity of a position where a protective sheet and an identification label sheet are stacked in the solar cell module according to the third embodiment of the present invention.

### DESCRIPTION OF EMBODIMENTS

A solar cell module and a method for manufacturing a solar cell module according to embodiments of the present invention will be described in detail below with reference to the accompanying drawings. The present invention is not limited to the embodiments, and can be modified as appropriate without departing from the scope of the invention. In the drawings described below, for the sake of understanding, the scale of each member may be different from that of actual products.

### First Embodiment

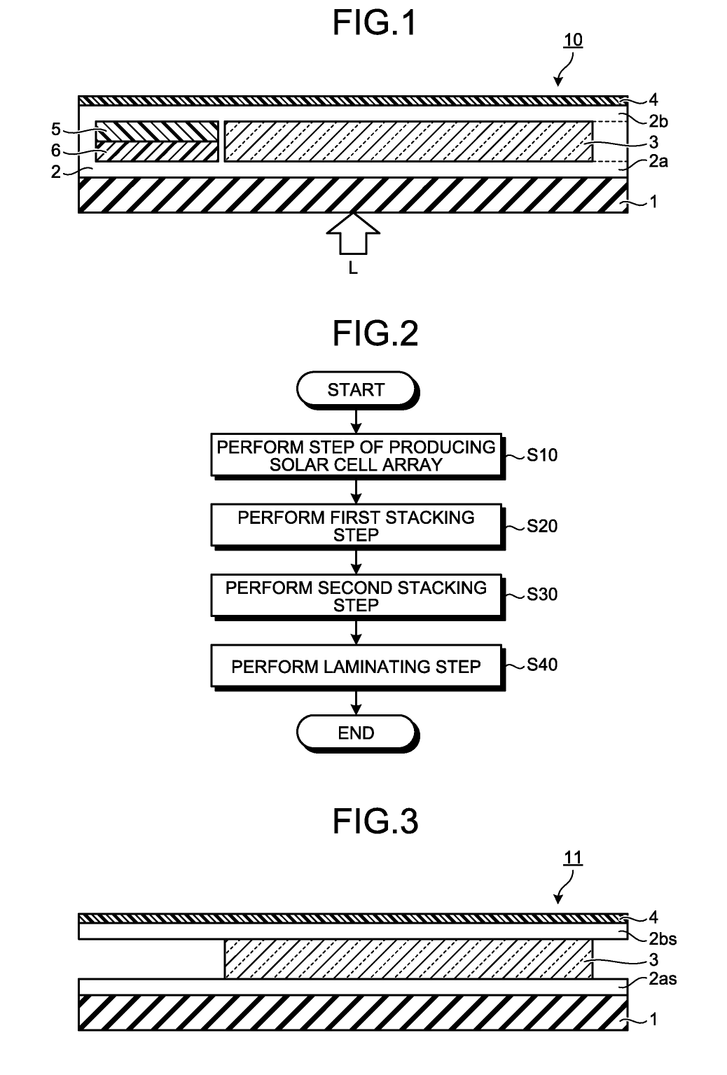

FIG. 1 is a schematic cross-sectional view illustrating a solar cell module 10 according to a first embodiment of the present invention. The solar cell module 10 according to the first embodiment includes a light transmissive substrate 1 that is a light-receiving-side protective member positioned on the light-receiving side, a back film 4 that is a backside cover film that serves as a backside protective member positioned on the backside opposite to a light-receiving surface, a sealing layer 2 that is interposed between the light transmissive substrate 1 and the back film 4, a solar cell array 3 in which a plurality of solar cells (not illustrated) are electrically connected and sealed inside the sealing layer 2, an identification label sheet 5 that is sealed inside the sealing layer 2 in a region where the identification label sheet 5 does not overlap the solar cells in the planar direction of the light transmissive substrate 1, and a protective sheet 6 that is sealed inside the sealing layer 2 in a state in which the protective sheet 6 is stacked on the identification label sheet 5 on the side of the light transmissive substrate 1. In the solar cell module 10, solar light L enters from the front-surface side of the light transmissive substrate 1.

A region of the sealing layer 2, which is located on the side of the light transmissive substrate 1 relative to the light-receiving surfaces of the solar cells, is referred to as a “light-receiving-side sealing layer 2a”. A region of the sealing layer 2, which is located on the side of the back film 4 relative to the light-receiving surface of the solar cells, is referred to as an “backside sealing layer 2b”.

Therefore, in a region of the solar cell module 10 where the solar cell array 3 is present in the planar direction of the light transmissive substrate 1, the light transmissive substrate 1, the light-receiving-side sealing layer 2a, the solar cell array 3, the backside sealing layer 2b, and the back film 4 are stacked in this order from the side where the solar light L enters. Further, in a region of the solar cell module 10, which does not overlap the solar cells, the light transmissive substrate 1, the light-receiving-side sealing layer 2a, the protective sheet 6, the identification label sheet 5, the backside sealing layer 2b, and the back film 4 are stacked in this order from the side where the solar light L enters.

The light transmissive substrate 1 is fixed to the light-receiving side of the light-receiving-side sealing layer 2a with an adhesive force of this light-receiving-side sealing layer 2a. As the light transmissive substrate 1, a glass substrate with light transmission properties and a weather resistance is used. While a glass substrate is used as the light transmissive substrate 1 in this case, it is also possible to use a resin plate or any other member as long as the member is made of a material with light transmission properties and a weather resistance.

The sealing layer 2 is made of thermosetting resin with light transmission properties, such as EVA resin that is a sealant commonly used for a solar cell module. In the present embodiment, EVA is used as a material of the sealing layer 2. However, the material of the sealing layer 2 is not limited to EVA. It is also possible to use other types of thermosetting resin as long as the material has light transmission properties, and is capable of sealing the solar cell array 3 by bonding the light transmissive substrate 1 and the solar cell array 3 together, and bonding the back film 4 and the solar cell array 3 together. As the material of the sealing layer 2 as described above, it is also possible to use an ethylene-ethyl acrylate copolymer, an ethylene-methyl acrylate copolymer, a polyolefin-based resin, a silicone-based resin, or any other type of resin.

It is effective to cross-link the sealing layer 2 in order to improve its weather resistance, strength, and adhesiveness with the light transmissive substrate 1 and the back film 4. As a cross-linking method, generation of a radical with heat is effective.

It is preferable for the sealing layer 2 to have ultraviolet absorbing properties. When the sealing layer 2 has ultraviolet absorbing properties, this suppresses degradation and discoloration of each member of the solar cell module 10 caused by ultraviolet rays of solar light, and therefore can improve the light resistance of each member of the solar cell module 10. Ultraviolet absorbent is evenly contained in the sealing layer 2, and therefore the sealing layer 2 can have ultraviolet absorbing properties. In the specification of the present invention, ultraviolet rays mean light with a wavelength in the ultraviolet spectrum.

Meanwhile, in order to improve the power generation performance of the solar cell module 10, it is preferable for the light-receiving-side sealing layer 2a to have less ultraviolet absorbing properties than the backside sealing layer 2b. When the light-receiving-side sealing layer 2a has less ultraviolet absorbing properties than those of the backside sealing layer 2b, the amount of ultraviolet rays to be absorbed by the light-receiving-side sealing layer 2a can be reduced. Accordingly, the solar cells can be irradiated with an increased amount of ultraviolet rays. Meanwhile, because of the ultraviolet absorbing properties, the backside sealing layer 2b can suppress degradation of the back film 4 caused by ultraviolet rays. The ultraviolet absorbing properties can be evaluated by comparing the amount of light in the ultraviolet spectrum between incident light and outgoing light. The incident light enters from the side of the light transmissive substrate 1 into the light-receiving-side sealing layer 2a or the backside sealing layer 2b. The outgoing light is the corresponding incident light that has passed through the light-receiving-side sealing layer 2a or the backside sealing layer 2b toward the back sheet, and has exited.

That is, in a case where the light-receiving-side sealing layer 2a has equal thickness to the backside sealing layer 2b, it is preferable for the light-receiving-side sealing layer 2a to have a lower content of ultraviolet absorbent in a specific thickness. In a case where the light-receiving-side sealing layer 2a has equal thickness to the backside sealing layer 2b, the content of ultraviolet absorbent in the light-receiving-side sealing layer 2a in a specific thickness is made lower than that in the backside sealing layer 2b. Therefore, the amount of ultraviolet rays to be absorbed in the light-receiving-side sealing layer 2a can be reduced, while an increased amount of ultraviolet rays can be irradiated to the solar cells. This improves the power generation performance of the solar cell module 10, and simultaneously can achieve a cost reduction as compared to a case where the light-receiving-side sealing layer 2a and the backside sealing layer 2b have equal content of ultraviolet absorbent. Further, it is allowable that the light-receiving-side sealing layer 2a does not have ultraviolet absorbing properties, that is, does not contain therein ultraviolet absorbent. In the solar cell module 10 according to the first embodiment, the light-receiving-side sealing layer 2a has ultraviolet absorbent whose content is lower than that of the backside sealing layer 2b.

The ultraviolet absorbent can be selected from among various types of commonly-known ultraviolet absorbent, and be used. For example, ultraviolet absorbent made of salicylic acid-based, benzophenone-based, benzotriazole-based, cyanoacrylate-based, or triazine-based organic compounds can be used.

In the solar cell array 3, a plurality of solar cells (not illustrated) are arrayed in a matrix on the same plane with a gap region between the solar cells. The solar cells are electrically connected in series by connecting electrodes provided on front and back surfaces of the adjacent solar cells with one another. As a solar cell that constitutes the solar cell array 3, a commonly-known solar cell such as a crystal-system solar cell can be used. The crystal-system solar cell is, for example, a silicon-based solar cell such as a monocrystalline silicon solar cell or a polycrystalline silicon solar cell. The crystal-system solar cell is not limited thereto.

The back film 4 is fixed to the backside of the backside sealing layer 2b with an adhesive force of this backside sealing layer 2b. As the back film 4, a weather-resistant resin sheet of PET, plastic, or the like is used. The backside cover film is not limited to the back film 4. Any other member such as a resin plate can be used as long as the member is made of a weather-resistant material.

The identification label sheet 5 is an identification management member made of a plate or sheet of base material of polymeric resin such as PET, polyethylene, polypropylene, polycarbonate, or acrylic. The individual identification number is noted on the surface of the base material. The identification label sheet 5 according to the first embodiment is made of PET. The solar cell module 10 is managed by the individual identification number for individually identifying and managing each individual solar cell module. The individual identification number is additionally linked with information such as module type, connector type, performance, and other characteristics. The individual identification number is printed in black or in a black type of color on the identification label sheet 5 by a printing method such as thermal transfer printing.

The identification label sheet 5 is made of resin. Therefore, when the identification label sheet 5 is irradiated with ultraviolet rays for a long period of time, the resin itself that is a base material of the identification label sheet 5 is discolored, and its color is changed to yellow or the like. When the identification label sheet 5 is discolored, the individual identification number noted on the identification label sheet 5 is difficult to identify or cannot be identified.

The protective sheet 6 is a sheet positioned on the light-receiving side of the identification label sheet 5, that is, on the side of the light transmissive substrate 1 to protect the identification label sheet 5. The protective sheet 6 is made of thermosetting resin material with light transmission properties, such as EVA or olefin. The protective sheet 6 according to the first embodiment is made of EVA.

The protective sheet 6 contains therein ultraviolet absorbent, and has ultraviolet absorbing properties. That is, the protective sheet 6 absorbs ultraviolet rays of the solar light L that has entered from the side of the light transmissive substrate 1, and has passed through the light-receiving-side sealing layer 2a. Due to this structure, the amount of ultraviolet rays in light entering into the identification label sheet 5 is reduced from the solar light that has entered from the side of the light transmissive substrate 1, and has passed through the light-receiving-side sealing layer 2a. The solar cell module 10 can therefore suppress discoloration of the identification label sheet 5 caused by ultraviolet rays of solar light that enters from the side of the light transmissive substrate 1, and can improve the light resistance of the identification label sheet 5.

The protective sheet 6 has a higher content of ultraviolet absorbent per unit volume than the light-receiving-side sealing layer 2a, and also has greater ultraviolet absorbing properties per unit volume than the light-receiving-side sealing layer 2a. That is, the protective sheet 6 has greater ultraviolet absorbing properties in a specific thickness in a direction vertical to the light transmissive substrate 1 than those of the light-receiving-side sealing layer 2a. This suppresses discoloration of the identification label sheet 5 caused by ultraviolet rays of the solar light L that enters from the side of the light transmissive substrate 1, and therefore improves the light resistance of the identification label sheet 5 as compared to a case where the protective sheet 6 is not provided on the light-receiving side of the identification label sheet 5, that is, a case where the light-receiving-side sealing layer 2a is located directly on the light-receiving side of the identification label sheet 5. That is, discoloration of the identification label sheet 5 caused by ultraviolet rays of solar light that enters from the side of the light transmissive substrate 1 is suppressed as compared to a structure in which a material of the protective sheet 6 is replaced with a material of the light-receiving-side sealing layer 2a.

The ultraviolet absorbing properties of the protective sheet 6 can be evaluated by comparing the amount of light in the ultraviolet spectrum between incident light and outgoing light. The incident light is light that enters from the side of the light transmissive substrate 1 into the protective sheet 6. The outgoing light corresponds to the incident light that has passed through the protective sheet 6, and has exited. The same applies to the ultraviolet absorbing properties of the light-receiving-side sealing layer 2a.

It is allowable that the content of ultraviolet absorbent in the protective sheet 6 is appropriately set such that the protective sheet 6 is capable of suppressing discoloration of the identification label sheet 5 for a desired period of time. The effect of suppressing discoloration of the identification label sheet 5 varies depending on the conditions such as an area where the solar cell module 10 is used, the type of ultraviolet absorbent, the content of ultraviolet absorbent in the protective sheet 6, and the thickness of the protective sheet 6. Therefore, it is sufficient that, in consideration of such conditions, the content of ultraviolet absorbent in the protective sheet 6 is determined appropriately within a range where this content is higher than that of the light-receiving-side sealing layer 2a, such that the protective sheet 6 is capable of suppressing discoloration of the identification label sheet 5 for a desired period of time.

It is preferable that the protective sheet 6 is positioned in such a region as to cover the entire region of the identification label sheet 5 in the planar direction of the light transmissive substrate 1. In a case where in the planar direction of the light transmissive substrate 1, there is a region where the identification label sheet 5 extends past the protective sheet 6, that is, a region where the identification label sheet 5 does not overlap the protective sheet 6, solar light enters into this region, where the amount of ultraviolet rays of the solar light is not reduced by the protective sheet 6. Therefore, in this region, the effect of suppressing discoloration of the identification label sheet 5 described above cannot be obtained.

The protective sheet 6 has greater ultraviolet absorbing properties than the light-receiving-side sealing layer 2a. This suppresses discoloration of the protective sheet 6 itself caused by ultraviolet rays of solar light that enters from the side of the light transmissive substrate 1. Accordingly, the protective sheet 6 itself has a greater light resistance than the light-receiving-side sealing layer 2a. This can suppress a case where the individual identification number noted on the identification label sheet 5 is difficult to identify or cannot be identified due to discoloration of the protective sheet 6 itself.

It is possible that the protective sheet 6 contains therein discoloration-preventing agent to have discoloration prevention properties. When the protective sheet 6 contains therein discoloration-preventing agent, this can further suppress discoloration of the protective sheet 6 itself. This can further suppress a case where the individual identification number noted on the identification label sheet 5 is difficult to identify or cannot be identified due to discoloration of the protective sheet 6 itself.

Next, a method for manufacturing the solar cell module 10 configured as described above is explained. FIG. 2 is a flowchart illustrating a procedure of the method for manufacturing the solar cell module 10 according to the first embodiment of the present invention. FIGS. 3 to 5 are schematic cross-sectional views illustrating the method for manufacturing the solar cell module 10 according to the first embodiment of the present invention.

First, at Step 10, a step of producing a solar cell array is performed. At the step of producing a solar cell array, first a plurality of solar cells is produced by a commonly-known method. The solar cells are then connected to each other by using a lead to form the solar cell array 3 in which the solar cells are electrically connected in series.

Next, at Step 20, the first stacking step is performed. At the first stacking step, as illustrated in FIG. 3, a first stacked body 11 is formed by sequentially stacking a light-receiving-side sealing layer sheet 2as made of EVA, the solar cell array 3, a backside sealing layer sheet 2bs made of EVA, and the back film 4 on the light transmissive substrate 1. The light-receiving-side sealing layer sheet 2as and the backside sealing layer sheet 2bs have equal outer dimensions which are greater than those of the solar cell array 3. For example, these sealing layer sheets 2as and 2bs have outer dimensions equal to those of the light transmissive substrate 1 and the back film 4. For example, the light-receiving-side sealing layer sheet 2as and the backside sealing layer sheet 2bs have equal thickness to each other. Due to this structure, at Step 30, a region into which the protective sheet 6 and the identification label sheet 5 are inserted can be secured between the light-receiving-side sealing layer sheet 2as and the backside sealing layer sheet 2bs. It is also possible for the light-receiving-side sealing layer sheet 2as and the backside sealing layer sheet 2bs to have smaller outer dimensions than those of the light transmissive substrate 1 and the back film 4 depending on the thickness of these sealing layer sheets 2as and 2bs.

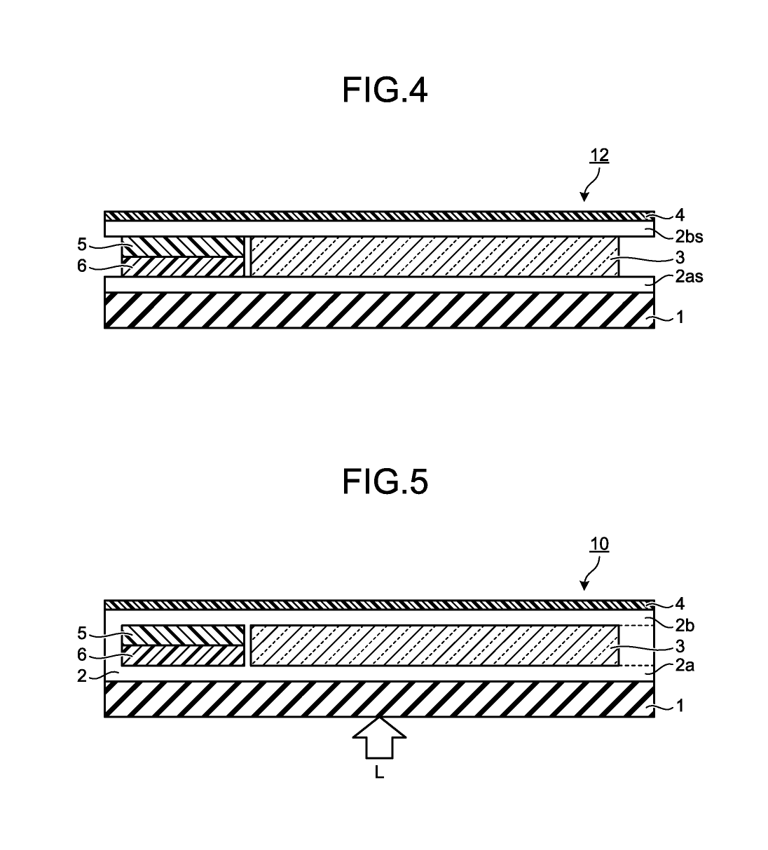

Next, at Step 30, the second stacking step is performed. As illustrated in FIG. 4, at the second stacking step, the protective sheet 6 made of EVA and the identification label sheet 5 made of PET are stacked on the first stacked body 11 formed at Step 20. At the time of stacking the protective sheet 6 and the identification label sheet 5, the protective sheet 6 is stacked on the light-receiving-side sealing layer sheet 2as in a region between the light-receiving-side sealing layer sheet 2as and the backside sealing layer sheet 2bs where the protective sheet 6 does not overlap the solar cell array 3, that is, where the solar cell array 3 is not located. The identification label sheet 5 is stacked between the protective sheet 6 and the backside sealing layer sheet 2bs. The protective sheet 6 and the identification label sheet 5 are located at such a position as not to shield the light-receiving surfaces of the solar cells in the solar cell array 3. Due to this structure, a second stacked body 12 formed by stacking the protective sheet 6 and the identification label sheet 5 on the first stacked body 11 is obtained.

Dimensions of the outline shape of the protective sheet 6 are equal to or slightly larger than those of the identification label sheet 5. For example, in the process of positioning the identification label sheet 5 and the protective sheet 6, a square-shaped identification label sheet 5 with its outer dimensions of approximately 150 mm×20 mm and thickness of approximately 0.125 mm, and a square-shaped protective sheet 6 with its outer dimensions of approximately 150 mm×20 mm and thickness of approximately 0.4 mm are layered, and then placed on the light-receiving-side sealing layer sheet 2as, while being held with tweezers near the center of these sheets 5 and 6. It is also possible to individually and subsequently stack the protective sheet 6 and the identification label sheet 5.

EVA is used for a material of the protective sheet 6. Therefore, when a stacked body of the protective sheet 6 and the identification label sheet 5 is inserted on the light-receiving-side sealing layer sheet 2as made of EVA with the protective sheet 6 situated on the side of the light-receiving-side sealing layer sheet 2as, then the protective sheet 6 and the light-receiving-side sealing layer sheet 2as come into close contact, and do not slide over each other. That is, because the protective sheet 6 and the light-receiving-side sealing layer sheet 2as are made of a material with the same properties as each other, this results in a greater friction force between their contact surfaces, so that these sheets 6 and 2as hardly slide over each other. This facilitates positioning of the protective sheet 6, and simultaneously can prevent the protective sheet 6 from sliding over the light-receiving-side sealing layer sheet 2as during the next laminating step. This can prevent the identification label sheet 5 from being misaligned by the sliding of the protective sheet 6, and from overlapping the solar cells during the subsequent laminating step. That is, a defective condition, in which the output of the solar cells is reduced because the identification label sheet 5 overlaps the solar cells and blocks the solar cells from receiving light, can be prevented.

In a case where the protective sheet 6 is not inserted, the identification label sheet 5 comes into contact with the light-receiving-side sealing layer sheet 2as. In this case, the contact surfaces between the identification label sheet 5 and the light-receiving-side sealing layer sheet 2as easily slide over each other. Therefore, the identification label sheet 5 is more likely to become misaligned.

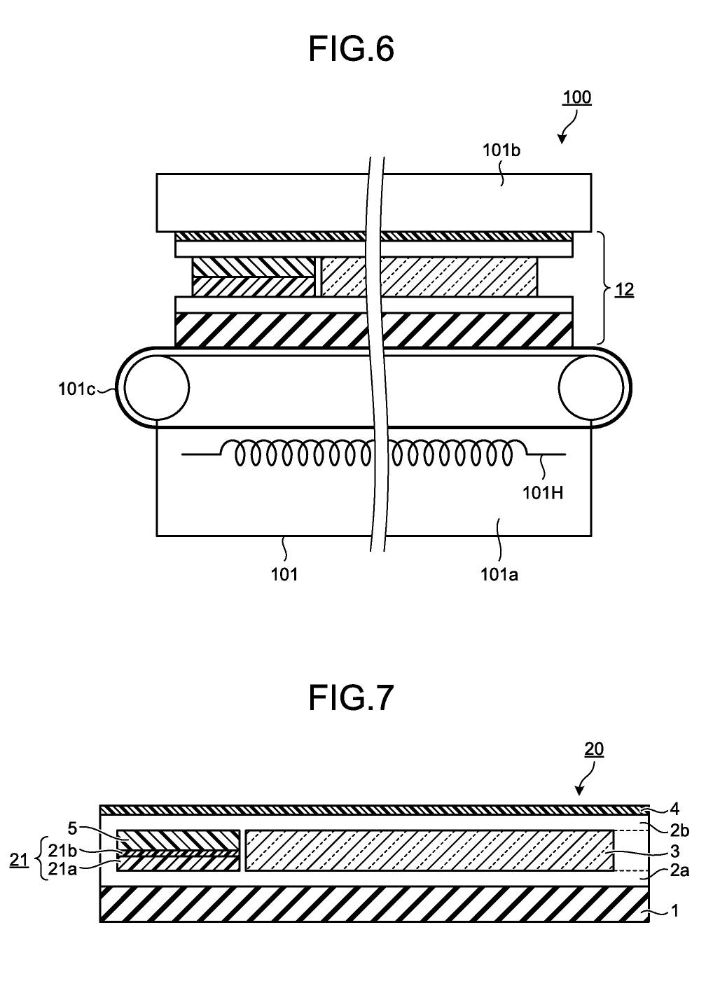

Subsequently, at Step 40, a laminating step is performed. At the laminating step, the second stacked body 12 is laminated by a laminate sealing process using a solar-cell-module manufacturing device 100 as illustrated in FIG. 6, and the solar cell array 3 is sealed inside the sealing layer 2. The light-receiving-side sealing layer sheet 2as and the backside sealing layer sheet 2bs have equal thickness. Therefore, in a region of the sealing layer 2 other than the stacked section of the protective sheet 6 and the identification label sheet 5, the light-receiving-side sealing layer sheet 2as and the backside sealing layer sheet 2bs are joined near the middle position between the light transmissive substrate 1 and the back film 4.

FIG. 6 is a schematic cross-sectional view illustrating the solar-cell-module manufacturing device 100 to be used for manufacturing the solar cell module 10 according to the first embodiment of the present invention. The solar-cell-module manufacturing device 100 is a commonly-known resin sealing device that is generally used for manufacturing a solar cell module, that is, a vacuum heating laminating device.

The solar-cell-module manufacturing device 100 includes a main body 101 and a cooling conveyor. The main body 101 includes a first member 101a that is positioned at the bottom, a second member 101b that has a function of pressing a melted sealant, and is positioned above the first member 101a, and an annular conveying sheet 101c that conveys the second stacked body 12. The first member 101a includes a heater 101H that heats the second stacked body 12. The case where the laminating step is performed in the atmosphere has been described. However, it is also possible that the solar-cell-module manufacturing device 100 is configured to laminate the second stacked body 12 in a vacuum.

The cooling conveyor is located downstream of the main body 101. The cooling conveyor has a function of air-cooling the second stacked body 12 discharged from the main body 101 after having been undergone a melting and pressurizing process, and a function of conveying the second stacked body 12. The cooling conveyor is configured by a plurality of rollers located in parallel. However, it is also possible that the cooling conveyor is configured by a conveying sheet and a conveying chain.

At the laminating step, in the solar-cell-module manufacturing device 100, the second stacked body 12 is located above the first member 101a, while being placed on the conveying sheet 101c. A melting and pressurizing step is then performed that is a laminate sealing process of heating the second stacked body 12 by using the heater 101H, and pressurizing the second stacked body 12 by the second member 101b in a state in which the light-receiving-side sealing layer sheet 2as and the backside sealing layer sheet 2bs have melted.

Thereafter, the second stacked body 12 is fed from the main body 101 to the cooling conveyor by rotation of the conveying sheet 101c. In the second stacked body 12, the melted light-receiving-side sealing layer sheet 2as and backside sealing layer sheet 2bs are cooled and hardened by the cooling conveyor. The second stacked body 12 is then conveyed by the cooling conveyor. In this manner, the individual members described above are integrated with each other as illustrated in FIG. 5. The solar cell module 10 according to the first embodiment is thus obtained in which the solar cell array 3 is sealed by the sealing layer 2, in which the light-receiving-side sealing layer sheet 2as and the backside sealing layer sheet 2bs are integrated.

In the above descriptions, the light-receiving-side sealing layer sheet 2as, the solar cell array 3, the backside sealing layer sheet 2bs, and the back film 4 are sequentially stacked on the light transmissive substrate 1 at Step 20, and thereafter the protective sheet 6 and the identification label sheet 5 are stacked at Step 30. However, the order of stacking the protective sheet 6 and the identification label sheet 5 is not limited thereto. It is also possible that after the light-receiving-side sealing layer sheet 2as and the solar cell array 3 are stacked on the light transmissive substrate 1, the protective sheet 6 and the identification label sheet 5 are stacked thereon, and thereafter the backside sealing layer sheet 2bs and the back film 4 are stacked sequentially. It is also possible that after the light-receiving-side sealing layer sheet 2as is stacked on the light transmissive substrate 1, the protective sheet 6 and the identification label sheet 5 are stacked, and thereafter the solar cell array 3, the backside sealing layer sheet 2bs, and the back film 4 are stacked sequentially.

As described above, in the solar cell module 10 according to the first embodiment, the protective sheet 6 is positioned on the light-receiving side of the identification label sheet 5. Due to this structure, the amount of ultraviolet rays in light entering into the identification label sheet 5 is reduced as compared to that of the solar light that has entered from the side of the light transmissive substrate 1, and has passed through the light-receiving-side sealing layer 2a. The solar cell module 10 can therefore suppress discoloration of the identification label sheet 5 caused by ultraviolet rays of solar light that enters from the side of the light transmissive substrate 1, and can improve the light resistance of the identification label sheet 5.

The solar cell module 10 according to the first embodiment includes the protective sheet 6. Therefore, even in a case where the light-receiving-side sealing layer 2a has a lower content of ultraviolet absorbent than the content of ultraviolet absorbent in the backside sealing layer 2b, it is still possible to suppress discoloration of the identification label sheet 5 caused by ultraviolet rays of solar light that enters from the side of the light transmissive substrate 1, and improve the light resistance of the identification label sheet 5.

In the solar cell module 10 according to the first embodiment, because the front side of the solar cells is not covered with the protective sheet 6, this can prevent ultraviolet irradiation to the solar cells from being blocked due to the protective sheet 6. This makes it possible to irradiate the solar cells with light in which the amount of ultraviolet rays is not reduced by the protective sheet 6, thereby improving the output of the solar cell module 10.

In the solar cell module 10 according to the first embodiment, the content of ultraviolet absorbent in the light-receiving-side sealing layer 2a is made lower than the content of ultraviolet absorbent in the backside sealing layer 2b. Therefore, the amount of ultraviolet rays to be absorbed in the light-receiving-side sealing layer 2a can be reduced, while an increased amount of ultraviolet rays can be irradiated to the solar cells. Due to this structure, the solar cell module 10 can achieve a cost reduction, and can simultaneously improve the output of the solar cell module 10, as compared to a case where the content of ultraviolet absorbent in the light-receiving-side sealing layer 2a is made equal to the content in the backside sealing layer 2b.

When a material with the same properties as the material of the light-receiving-side sealing layer sheet 2as is used for the protective sheet 6, it is possible to suppress a defective condition in which the output of the solar cells is reduced due to misalignment of the identification label sheet 5 caused by the sliding of the protective sheet 6 during the laminating step.

Therefore, in the solar cell module 10 according to the first embodiment, it is possible to suppress discoloration of the identification label sheet 5, and can obtain a higher-output lower-cost solar cell module.

### Second Embodiment

FIG. 7 is a schematic cross-sectional view illustrating a solar cell module 20 according to a second embodiment of the present invention. The solar cell module 20 according to the second embodiment is different from the solar cell module 10 according to the first embodiment in that the solar cell module 20 includes a protective sheet 21 instead of the protective sheet 6. The protective sheet 21 has a structure in which the protective sheet 6 and a PET sheet are stacked and integrated with each other.

The protective sheet 21 is configured by staking a protective layer 21a having the same configuration and function of the protective sheet 6, and a PET sheet layer 21b made of PET. In the protective sheet 21, the protective layer 21a arranged on the side of the light-receiving-side sealing layer 2a, and the PET sheet layer 21b arranged on the side of the identification label sheet 5, are stacked.

The protective sheet 21 can be used as an insulating sheet. Therefore, in a case where an insulating sheet is used in a solar cell module, parts sharing can be achieved. An output lead (not illustrated) with its one end led out to the backside of the solar cell module 20 is connected to the solar cell array 3. In this case, in order to reliably insulate the output lead from its peripheral region, an insulating sheet is provided in a region around the output lead.

Similarly to the protective sheet 6, the protective sheet 21 is positioned on the light-receiving side of the identification label sheet 5, that is, on the side of the light transmissive substrate 1. The protective sheet 21 includes the protective layer 21a having the same function as that of the protective sheet 6, and therefore has ultraviolet absorbing properties. That is, the protective sheet 21 absorbs ultraviolet rays of solar light that has entered from the side of the light transmissive substrate 1. Accordingly, the amount of ultraviolet rays in light entering into the identification label sheet 5 is reduced as compared to that of the solar light L that has entered from the side of the light transmissive substrate 1. According to the solar cell module 20, it is possible to suppress discoloration of the identification label sheet 5 caused by ultraviolet rays of solar light that enters from the side of the light transmissive substrate 1, and improve the light resistance of the identification label sheet 5.

Similarly to the protective sheet 6, it is preferable for the protective sheet 21 to be positioned in a region where the protective sheet 21 covers the entire region of the identification label sheet 5 in the planar direction of the light transmissive substrate 1.

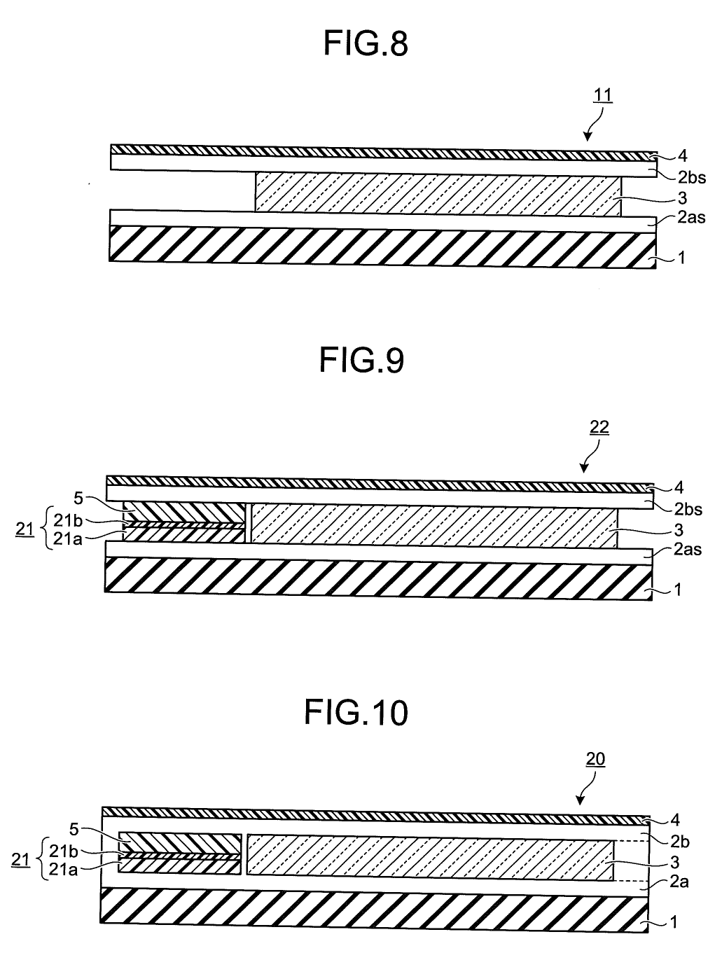

Next, a method for manufacturing the solar cell module 20 configured as described above is explained. Because the basic steps of the method for manufacturing the solar cell module 20 are the same as those of the method for manufacturing the solar cell module 10, the manufacturing method is described with reference to FIG. 2. FIGS. 8 to 10 are schematic cross-sectional views illustrating the method for manufacturing the solar cell module 20 according to the second embodiment of the present invention.

In the same manner as in the first embodiment, the step of producing a solar cell array is performed at Step 10. Next, at Step 20, the first stacking step is performed at which the first stacked body 11 is formed as illustrated in FIG. 8.

Subsequently, at Step 30, the second stacking step is performed. In the second embodiment, as illustrated in FIG. 9, at the second stacking step, the protective sheet 21 and the identification label sheet 5 are stacked on the first stacked body 11 formed at Step 20. At the stacking of the protective sheet 21 and the identification label sheet 5, the protective sheet 21 is stacked on the light-receiving-side sealing layer sheet 2as in a region between the light-receiving-side sealing layer sheet 2as and the backside sealing layer sheet 2bs where the protective sheet 21 does not overlap the solar cell array 3. Further, the identification label sheet 5 is stacked between the protective sheet 21 and the backside sealing layer sheet 2bs. The protective sheet 21 and the identification label sheet 5 are located at such a position as not to shield the light-receiving surfaces of the solar cells in the solar cell array 3. Due to this structure, a third stacked body 22 formed by stacking the protective sheet 21 and the identification label sheet 5 on the first stacked body 11 is obtained.

Dimensions of the outline shape of the protective sheet 21 are equal to, or slightly larger than, those of the identification label sheet 5. For example, in the process of positioning the identification label sheet 5 and the protective sheet 21, a square-shaped identification label sheet 5 with its outer dimensions of approximately 150 mm×20 mm and thickness of approximately 0.125 mm, and a square-shaped protective sheet 21 with its outer dimensions of approximately 150 mm×20 mm and thickness of approximately 0.45 mm are layered, and then placed on the light-receiving-side sealing layer sheet 2as, while being held with tweezers near the center of these sheets 5 and 21. It is also possible to individually and subsequently stack the protective sheet 21 and the identification label sheet 5.

EVA is used for a material of the protective layer 21a of the protective sheet 21. Therefore, when the protective sheet 21 is inserted on the light-receiving-side sealing layer sheet 2as made of EVA, then the protective layer 21a and the light-receiving-side sealing layer sheet 2as come into close contact, and do not slide over each other. That is, because the protective layer 21a and the light-receiving-side sealing layer sheet 2as are made of a material with the same properties as each other, this results in a greater friction force between their contact surfaces, so that these sheets 21 and 2as are not likely to slide over each other. This facilitates positioning of the protective sheet 21, and simultaneously can prevent the protective sheet 21 from sliding during the next melting and pressurizing step. This can prevent the identification label sheet 5 from being misaligned by the sliding of the protective sheet 21, and from overlapping the solar cells during the subsequent laminating step. That is, a defective condition, in which the output of the solar cells is reduced because the identification label sheet 5 overlaps the solar cells and blocks the solar cells from receiving light, can be suppressed.

In a case where the protective sheet 21 is not inserted, the identification label sheet 5 made of PET comes into contact with the light-receiving-side sealing layer sheet 2as made of EVA. In this case, the contact surfaces between the identification label sheet 5 and the light-receiving-side sealing layer sheet 2as easily slide over each other. Therefore, the identification label sheet 5 is more likely to become misaligned.

In the configuration according to the second embodiment, the identification label sheet 5 made of PET comes into contact with the PET sheet layer 21b made of PET. The identification label sheet 5 and the PET sheet layer 21b are made of an identical PET material. This results in a greater friction force between the contact surfaces of the identification label sheet 5 and the PET sheet layer 21b because PET and PET come into contact with each other in the contact surfaces. Therefore, the contact surfaces are not likely to slide over each other. Further, the contact surface of the protective sheet 21 on the side of the light-receiving-side sealing layer sheet 2as is made of thermosetting resin identically to the light-receiving-side sealing layer sheet 2as. This results in a greater friction force between the contact surfaces of the protective sheet 21 and the light-receiving-side sealing layer sheet 2as because both are made of EVA, for example. Therefore, these contact surfaces are not likely to slide over each other.

That is, the protective sheet 21 has a material with the same properties as the identification label sheet 5 on one side, while having a material with the same properties as the light-receiving-side sealing layer sheet 2as on the other side. Both of the materials are integrated into the protective sheet 21. This protective sheet 21 is used and positioned in such a manner that the materials with the same properties come into contact with each other. Therefore, a greater friction force is exerted on the contact surfaces between the identification label sheet 5 and the protective sheet 21. This can prevent the identification label sheet 5 from becoming misaligned, and from overlapping the solar cells during the subsequent laminating step. That is, a defective condition, in which the output of the solar cells is reduced because the identification label sheet 5 overlaps the solar cells and blocks the solar cells from receiving light, can be prevented.

In the second embodiment, the protective sheet 21 is a stacked body of an EVA layer and a PET layer. PET is stiffer, that is, has greater rigidity than EVA. This can prevent the protective sheet 21 from sagging due to bending of the protective sheet 21 during the process of inserting the protective sheet 21, and facilitates the process of inserting the protective sheet 21. That is, by forming the protective sheet 21 from a stacked body of an EVA layer and a PET layer, the effects of preventing sliding of the protective sheet 21, and facilitating the insertion process can both be achieved simultaneously.

Thereafter, at Step 40, in the same manner as in the first embodiment, the laminating step is performed on the third stacked body 22. Therefore, as illustrated in FIG. 10, the solar cell module 20 according to the second embodiment is obtained.

As described above, in the solar cell module 20 according to the second embodiment, the protective sheet 21 having the same function as that of the protective sheet 6 is positioned on the light-receiving side of the identification label sheet 5. Due to this structure, in the solar cell module 20, the same effects as those of the solar cell module 10 according to the first embodiment can be derived, so that a higher-output lower-cost solar cell module can be obtained.

In the solar cell module 20 according to the second embodiment, the protective sheet 21 is composed of a stacked body of an EVA layer and a PET layer. Due to this configuration, in the solar cell module 20, it is possible to simultaneously achieve both of the effects of preventing sliding of the protective sheet 21 in the process of inserting the protective sheet 21, and facilitating the insertion process. A defective condition, in which the output of the solar cells is reduced due to misalignment of the identification label sheet 5 during the laminating step, can be suppressed.

### Third Embodiment

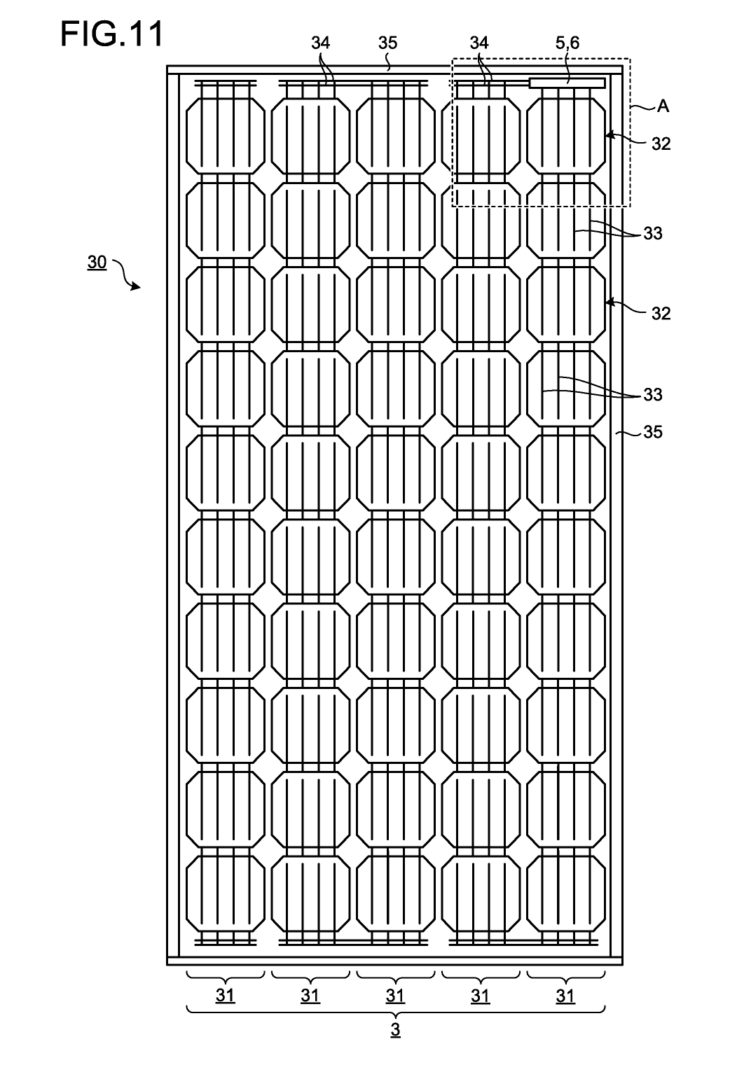

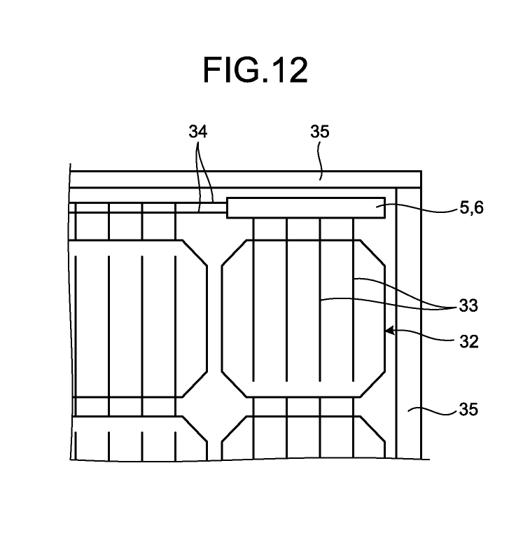

FIG. 11 is a schematic plan view illustrating a solar cell module 30 according to a third embodiment of the present invention. FIG. 12 is an enlarged diagram illustrating an enlarged region in the vicinity of the position where the protective sheet 6 and the identification label sheet 5 are stacked in the solar cell module 30 according to the third embodiment of the present invention. FIG. 12 is a diagram illustrating an enlarged region A in FIG. 11. FIGS. 11 and 12 focus on the solar cell array 3, the protective sheet 6, and the identification label sheet 5, and therefore illustrate a state in which the solar cell array 3, the protective sheet 6, and the identification label sheet 5 are seen through some of the other members.

The solar cell module 30 according to the third embodiment has a configuration in which the protective sheet 6 is positioned so as to overlap inter-string connection wires 34 on the basis of the configuration of the solar cell module 10 according to the first embodiment described above. The solar cell array 3 includes solar cell strings 31 in each of which a plurality of solar cells 32 are wired and electrically connected in series. The solar cell string 31 includes a plurality of solar cells 32 arrayed in a first array direction, and the inter-string connection wires 34. The solar cells 32 are spaced apart from each other by a predetermined distance in the first array direction, and are regularly arrayed substantially on the same plane. Two adjacent solar cells 32 are electrically connected in series to each other by inter-cell connection wires 33.

A plurality of solar cell strings 31 are spaced apart from each other by a predetermined distance in a second array direction, and are regularly arrayed on substantially the same plane. Two adjacent solar cell strings 31 are electrically connected in series to each other by the inter-string connection wires 34. In the third embodiment, five solar cell strings 31, in each of which 10 pieces of solar cells 32 are electrically connected in series, are further wired and electrically connected in series to constitute a single long solar cell array 3.

The inter-string connection wires 34 are positioned in a region between the solar cell strings 31 and a frame 35 that is attached to surround the outer periphery of the solar cell module 30. This region is a region that can be visually recognized from the light-receiving side of the solar cell module 30.

The solar cell module 30 according to the third embodiment has a configuration in which the protective sheet 6 is positioned so as to overlap the inter-string connection wires 34 in contrast to the configuration of the solar cell module 10 on the basis of the first embodiment described above. That is, at the position where the identification label sheet 5 is stacked in the solar cell module 30 according to the third embodiment, the light transmissive substrate 1, the light-receiving-side sealing layer 2a, the protective sheet 6, the identification label sheet 5, the inter-string connection wires 34, the backside sealing layer 2b, and the back film 4 are stacked in this order from the side where the solar light L enters. The solar cell module 30 according to the third embodiment can be produced by the same method as that of the solar cell module 10 except that the protective sheet 6 and the identification label sheet 5 are provided so as to overlap the inter-string connection wires 34.

Similarly to the solar cell module 10 according to the first embodiment described above, in the solar cell module 30 according to the third embodiment, it is possible to suppress discoloration of the identification label sheet 5, and a higher-output lower-cost solar cell module can be obtained.

In the solar cell module 30 according to the third embodiment, the protective sheet 6 and the identification label sheet 5 can be held by the inter-string connection wires 34 at the laminating step described above. This can further suppress misalignment of the identification label sheet 5 during the laminating step. In this case also, similarly to the first embodiment, a material with the same properties as those of the light-receiving-side sealing layer sheet 2as is used for the protective sheet 6. This can suppress a defective condition in which the output of the solar cells is reduced due to misalignment of the identification label sheet 5 caused by sliding of the protective sheet 6 during the laminating step.

The protective sheet 6 is provided so as to overlap the inter-string connection wires 34, so that the identification label sheet 5 can be provided at a position where the identification label sheet 5 can be visually recognized from outside, without increasing the outline shape of the solar cell module 30.

The protective sheet 6 has outer dimensions equal to or larger than those of the identification label sheet 5 as described above. It is preferable for the protective sheet 6 to be positioned in a region where the protective sheet 6 does not overlap the solar cells 32, and covers the entire region of the identification label sheet 5 in the planar direction of the light transmissive substrate 1.

Similarly, the solar cell module 20 according to the second embodiment described above can also have a configuration in which the protective sheet 21 is positioned so as to overlap the inter-string connection wires 34. That is, the solar cell module 20 can have a configuration in which the light transmissive substrate 1, the light-receiving-side sealing layer 2a, the protective sheet 21, the identification label sheet 5, the inter-string connection wires 34, the backside sealing layer 2b, and the back film 4 are stacked sequentially in this order from the side where the solar light L enters.

As described above, in the solar cell module 30 according to the third embodiment, the protective sheet 6 or the protective sheet 21 is provided so as to overlap the inter-string connection wires 34. Due to this configuration, in the solar cell module 30 according to the third embodiment, the identification label sheet 5 can be provided at a position where the identification label sheet 5 can be visually recognized from outside, without increasing the outline shape of the solar cell module.

The configurations described in the above embodiments are only examples of the contents of the present invention. The configurations can be combined with other well-known techniques, and a part of each configuration can be omitted or modified without departing from the scope of the present invention.

### REFERENCE SIGNS LIST

1 light transmissive substrate, 2 sealing layer, 2a light-receiving-side sealing layer, 2as light-receiving-side sealing layer sheet, 2b backside sealing layer, 2bs backside sealing layer sheet, 3 solar cell array, 4 back film, 5 identification label sheet, 6 protective sheet, 10, 30 solar cell module, 11 first stacked body, 12 second stacked body, 20 solar cell module, 21 protective sheet, 21a protective layer, 21b polyethylene terephthalate sheet layer, 22 third stacked body, 31 solar cell string, 32 solar cell, 33 cell-to-cell connection wire, 34 inter-string connection wire, 35 frame, 100 solar-cell-module manufacturing device, 101 main body, 101H heater, 101a first member, 101b second member, 101c conveying sheet, L solar light.

1. A solar cell module comprising:
a light-receiving-side protective member that is positioned on a light-receiving side, and has light transmission properties;
a backside protective member that is positioned on a backside opposite to a light-receiving surface;
a sealing layer that is made of resin with light transmission properties, and interposed between the light-receiving-side protective member and the backside protective member;
a plurality of solar cells that are electrically connected and sealed inside the sealing layer;
an identification label sheet that is sealed inside the sealing layer in a region different from a region of the solar cells in a planar direction of the light-receiving-side protective member, and that is made of resin on which identification management information is noted; and
a protective sheet that is stacked on the identification label sheet on a side of the light-receiving-side protective member, sealed inside the sealing layer, made of resin with light transmission properties, and contains therein ultraviolet absorbent, wherein
the sealing layer includes a light-receiving-side sealing layer positioned on a side of the light-receiving-side protective member relative to light-receiving surfaces of the solar cells in a thickness direction of the sealing layer, and
the protective sheet has greater ultraviolet absorbing properties in a specific thickness than the light-receiving-side sealing layer.

2. The solar cell module according to claim 1, wherein a backside sealing layer of the sealing layer has ultraviolet absorbing properties, where the backside sealing layer is positioned on a side of the backside protective member relative to the back surfaces of the solar cells opposite to the light-receiving surfaces in the thickness direction of the sealing layer.

3. The solar cell module according to claim 2, wherein the light-receiving-side sealing layer has less ultraviolet absorbing properties than the backside sealing layer.

4. The solar cell module according to claim 1, wherein the protective sheet includes a resin layer with higher rigidity than the protective sheet on a side of the backside protective member.

5. The solar cell module according to claim 1, wherein the identification label sheet and the protective sheet are located on a connection wire for connecting the solar cells to each other.

6. A method for manufacturing a solar cell module, comprising:
a first step of forming a first stacked body by sequentially stacking a light-receiving-side sealing layer sheet that is made of resin with light transmission properties, and that serves as a sealing layer, a plurality of solar cells that are electrically connected, a backside sealing layer sheet that serves as a sealing layer, and a backside protective member on a light-receiving-side protective member with light transmission properties;
a second step of forming a second stacked body by sequentially stacking a protective sheet and an identification label sheet on the light-receiving-side sealing layer sheet in a region different from a region of the solar cells between the light-receiving-side sealing layer sheet and the backside sealing layer sheet, where the protective sheet contains therein ultraviolet absorbent, is made of resin with light transmission properties, and has greater ultraviolet absorbing properties in a specific thickness than the light-receiving-side sealing layer sheet, and where the identification label sheet is made of resin on which identification management information is noted; and
a third step of heating and pressurizing the second stacked body to form a solar cell module.

7. The method for manufacturing a solar cell module according to claim 6, wherein the backside sealing layer sheet contains therein ultraviolet absorbent.

8. The method for manufacturing a solar cell module according to claim 7, wherein the light-receiving-side sealing layer sheet contains therein a lower content of the ultraviolet absorbent than the backside sealing layer sheet.

9. The method for manufacturing a solar cell module according to claim 6, wherein the protective sheet includes a resin layer with higher rigidity than the protective sheet on a side of the identification label sheet.

10. The method for manufacturing a solar cell module according to claim 6, wherein the identification label sheet and the protective sheet are located on a connection wire for connecting the solar cells to each other.

11. The method for manufacturing a solar cell module according to claim 6, wherein the light-receiving-side sealing layer sheet and the protective sheet are made of resin material with same properties as each other.

12. The method for manufacturing a solar cell module according to claim 6, wherein the protective sheet is an insulating sheet.
